(19) United States
(12) Patent Application Publication
(10) Pub. No.: US 2026/0255686 A1
(43) Pub. Date: Aug. 27, 2026

(54) NANOSHEET DIODE-TRIGGERED SILICON CONTROLLED-RECTIFIER

(71) Applicant: INTERNATIONAL BUSINESS MACHINES CORPORATION, ARMONK, NY (US)

(72) Inventors: Anindya Nath, Watervliet, NY (US); Robert Gauthier, Williston, VT (US); Masoud Zabihi, Schenectady, NY (US); Anthony I-Chih Chou, Guilderland, NY (US); Md Khaled Hassan, Albany, NY (US)

(21) Appl. No.: 19/063,228

(22) Filed: Feb. 25, 2025

(51) Int. Cl. H10D 89/60; H10D 84/01; H10D 84/83

(52) U.S. Cl. CPC H10D 89/611; H10D 84/0151; H10D 84/832; H10D 89/713

(57) ABSTRACT

A semiconductor device includes a true two-terminal diode with a first terminal and a second terminal, and an electrostatic discharge device, ESD, electrically connected to the diode, the ESD comprising an anode and a cathode. The diode is a triggering element and is an operative to modulate a trigger voltage of the ESD, and wherein an ESD event occurs via the anode.

### BACKGROUND

### Technical Field

The present disclosure generally relates to semiconductors, and more particularly, to nanosheet diode-triggered silicon-controlled rectifier structure, and methods of creation thereof.

### Description of Related Art

The continuous miniaturization of transistors and their increasing density on chips are hallmark innovations in the semiconductor industry, closely following Moore’s Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes a device includes a true two-terminal diode with a first terminal and a second terminal, and an electrostatic discharge device, ESD, electrically connected to the diode, the ESD comprising an anode and a cathode. The diode is a triggering element and is an operative to modulate a trigger voltage of the ESD, and wherein an ESD event occurs via the anode. In one embodiment, the ESD is at least one of: a silicon-controlled rectifier, and a bipolar junction transistor.

In one embodiment, the semiconductor device includes a substrate, and the substrate is a bulk silicon substrate.

In one embodiment, the semiconductor device includes one or more P-type doped regions, one or more N-type doped regions, a first well region, and a second well region adjacent to the first well region. The first well region and the second well region are located below the one or more P-type doped regions and the one or more N-type doped region.

In one embodiment, the semiconductor device includes a set of shallow trench isolation (STI) below the one or more P-type doped regions and the one or more N-type doped regions and within the first well region and the second well region, and a set of gate regions on two ends of each of the one or more N-type doped regions and the one or more P-type doped regions.

In one embodiment, each of the one or more N-type doped regions and the one or more P-type doped regions includes a plurality of nano-sheet channels between a corresponding doped region and a gate region.

In one embodiment, the plurality of nano-sheet channels includes alternative layers extended horizontally between the corresponding doped region and the gate region.

In one embodiment, the alternative layers include silicon. According to an embodiment, a method of fabricating a semiconductor device includes forming a diode, wherein the diode is a true two-terminal diode with a first terminal and a second terminal, forming an electrostatic discharge device, ESD comprising an anode and a cathode, and electrically connecting the ESD to the diode. The diode is a triggering element and is operative to modulate a trigger voltage of the ESD, and an ESD event occurs via the anode.

In one embodiment, the ESD is at least one of: a silicon-controlled rectifier, and a bipolar junction transistor.

In one embodiment, the method includes forming a substrate, which is a bulk silicon substrate.

In one embodiment, the method includes forming one or more P-type doped regions, forming one or more N-type doped regions, forming a first well region, and forming a second well region adjacent to the first well region. The first well region and the second well region are located below the one or more P-type doped regions and the one or more N-type doped region.

In one embodiment, the method includes forming a set of shallow trench isolation (STI) below the one or more P-type doped regions and the one or more N-type doped regions and within the first well region and the second well region, and forming a set of gate regions on two ends of each of the one or more N-type doped regions and the one or more P -type doped regions.

In one embodiment, forming the one or more N-type doped regions and the one or more P-type doped regions includes forming a plurality of nano-sheet channels between a corresponding doped region and a gate region.

In one embodiment, forming the plurality of nano-sheet channels includes forming alternative layers extended horizontally between the corresponding doped region and the gate region.

In one embodiment, the alternative layers include silicon.

According to an embodiment, a semiconductor device includes a diode, and an electrostatic discharge device, ESD, electrically connected to the diode. The ESD is at least one of: a silicon-controlled rectifier, or a bipolar junction transistor.

In one embodiment, the semiconductor device includes one or more P-type doped regions, one or more N-type doped regions, a first well region, and a second well region adjacent to the first well region. The first well region and the second well region are located below the one or more P-type doped regions and the one or more N-type doped region.

In one embodiment, the semiconductor device includes a set of shallow trench isolation (STI) below the one or more P-type doped regions and the one or more N-type doped regions and within the first well region and the second well region, and a set of gate regions on two ends of each of the one or more N-type doped regions and the one or more P-type doped regions.

In one embodiment each of the one or more N-type doped regions and the one or more P-type doped regions includes a plurality of nano-sheet channels between a corresponding doped region and a gate region, the plurality of nano-sheet channels comprises alternative layers extended horizontally between the corresponding doped region and the gate region, and the alternative layers include silicon.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a conceptual schematic diagram of an ESD device.

FIG. 1B illustrates different operation regions of an ESD device, including during the normal circuit operation voltage range, ESD operating window during an ESD event, and the failure region of the diagram of FIG. 1A.

FIGS. 2A illustrates a cross-sectional view of a conventional diode/bipolar string triggered electrostatic discharge device and its circuitry.

FIGS. 2B-2D illustrate circuitry of the semiconductor device shown in FIG. 2A.

FIG. 2E is an I-V graph of the semiconductor device shown in FIG. 2A.

FIG. 3A-3B illustrate a semiconductor device, in accordance with an embodiment.

FIG. 4A-4B illustrates exemplary circuitry of the semiconductor device shown in FIGS. 3A-3B, respectively.

FIGS. 5A-5B illustrate top views of the semiconductor device, in accordance with some embodiments.

FIGS. 6A-6E illustrate the process acts to fabricate the semiconductor device, in accordance with some embodiments.

FIG. 6F illustrates a top view of the semiconductor device during the process acts as shown in FIGS. 6A-6E.

FIG. 7 illustrates a block diagram of a method for forming the semiconductor device, in accordance with an embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

In foundry technology, developing a complete portfolio of electrostatic discharge (ESD) protection devices is important to support the diverse types of input/output (I/O) configurations used in advanced semiconductor designs. ESD protection devices can safeguard sensitive electronic components against high-voltage spikes and unintended electrical discharges, which can occur during manufacturing, assembly, or end-use handling. As technology scales down to nodes such as 2nm and below, achieving robust ESD protection becomes increasingly challenging due to the ultra-small geometries and reduced breakdown voltages of modern transistors.

Key types of ESD devices for a comprehensive protection solution include NPNP or PNPN structures, which are typically implemented as thyristors or silicon-controlled rectifiers (SCRs). These devices, characterized by their four-layer structure of alternating P- and N-type regions, can absorb and divert large amounts of charge during an ESD event. The thyristor, in particular, operates as a controlled switch with two stable states, enabling it to withstand high-voltage transients without triggering during normal circuit operation. An SCR, on the other hand, offers even more robust ESD protection, as it can latch into a low-resistance state when triggered, allowing it to handle higher current levels than typical ESD diodes or resistive networks. However, as scaling progresses to the 2nm node and below, there are disadvantages in current technology such as the breakdown voltage, leakage characteristics, and latch-up immunity of the devices.

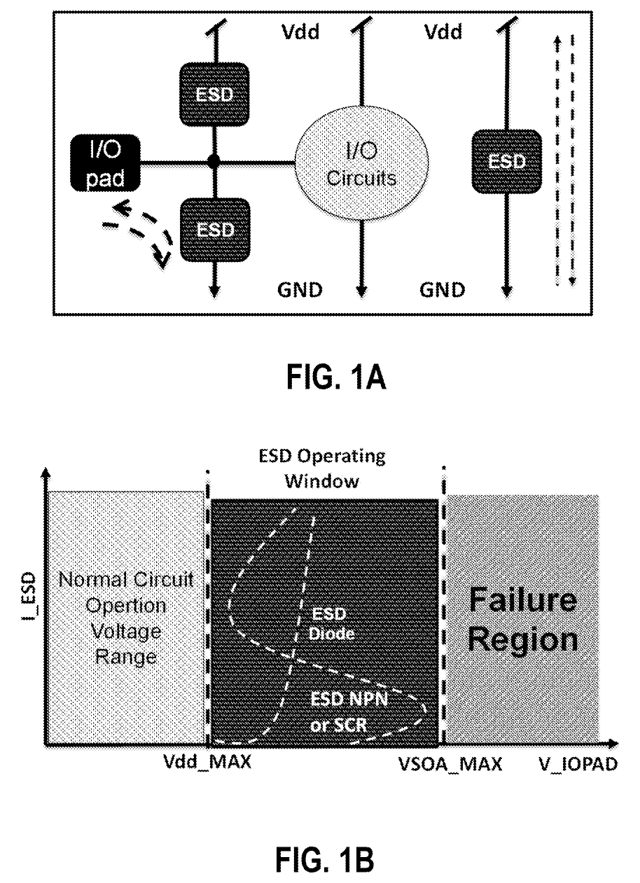

FIGS. 1A-1B illustrate schematically an ESD device operation during the normal circuit operation voltage range, ESD operating window during an ESD event, and the failure region.

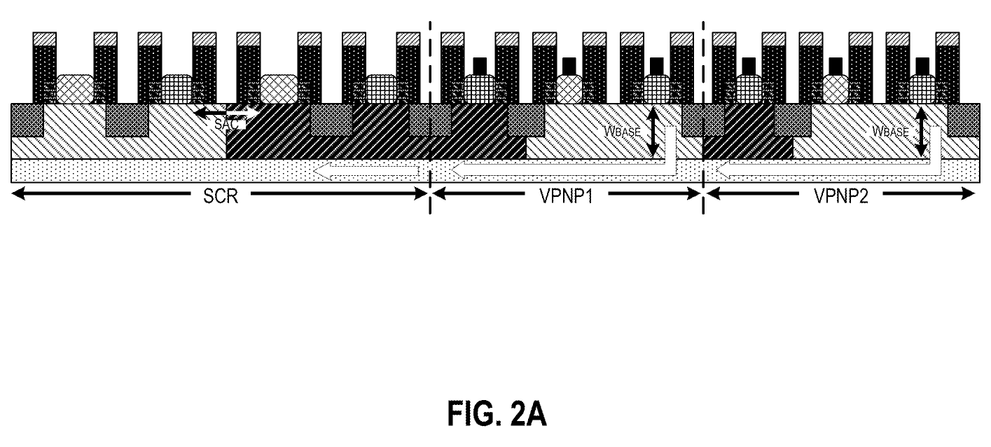

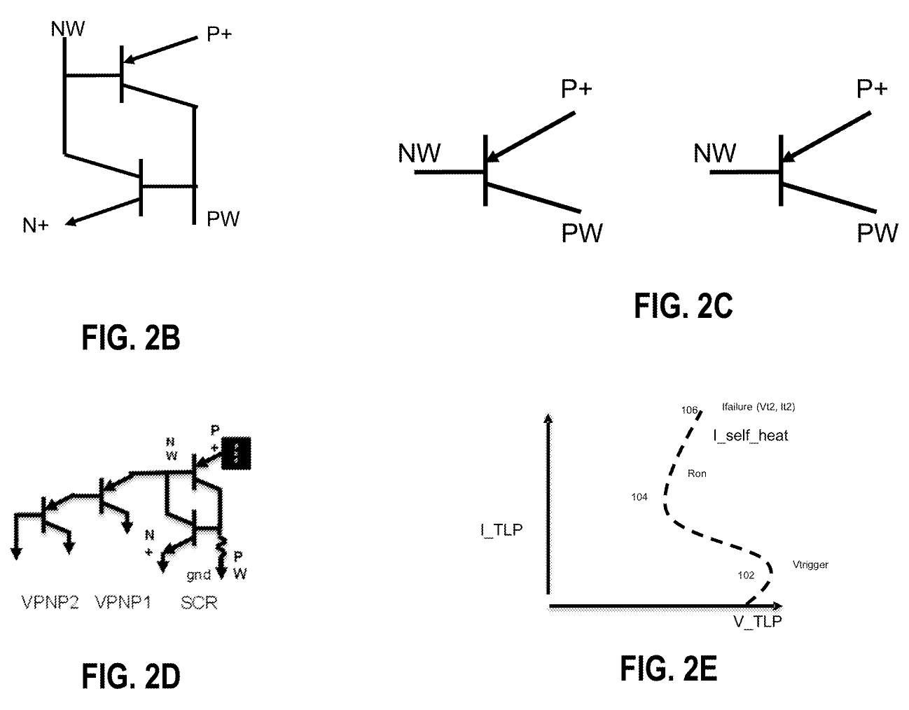

FIGS. 2A-2E illustrate a conventional diode/bipolar string triggered electrostatic discharge device and its circuitry. The device shown in FIG. 2B includes STI below the base, while the device shown in FIG. 2A lacks such STI below the base. A diode/bipolar string-triggered electrostatic discharge (ESD) protection device is designed to safeguard sensitive electronic components from voltage spikes due to ESD events by creating a controlled discharge path that diverts excessive current safely away from protected circuitry. Under normal operating conditions, the ESD protection device remains in a high-impedance, non-conductive state, isolating itself from the circuit to prevent interference with the device’s usual functionality. The diode or bipolar junction transistor (BJT) string is reverse-biased or configured in such a way that it does not conduct any significant current, e.g., 1 micro-Ampere or less, under standard voltage levels, ensuring that the protection device remains inactive.

The I-V graph of a diode/bipolar string triggered ESD protection device typically exhibits distinct regions that correspond to its behavior under varying voltage and current conditions. At the pre-trigger current region (point 102), the device is in its off state, with only a small leakage current flowing through it. This is typically a low-current, high-resistance state. The voltage increases with minimal current flow until it reaches the trigger voltage. At the snap-back region (from point 102 to point 104), as the voltage reaches the trigger threshold, the device transitions into conduction mode. This region is characterized by negative resistance, where an increase in current results in a decrease in voltage across the device. This snap-back effect occurs due to the activation of the bipolar transistor within the structure, which leads to a significant reduction in the device's resistance and allows current to flow more freely. At the high current conduction region (from point 104 to point 106), the device conducts high levels of current as it clamps the voltage at a safe level to protect downstream circuitry. The onset of self-heating becomes evident as the device handles high currents, which may result in a slight upward curvature in the I-V characteristic due to thermal effects increasing the resistance slightly.

When an ESD event occurs, it introduces a rapid and high-voltage spike, which can be (by way of example and not limitation) between 2,000 to 25,000 volts and at rise times of 0.7 to 100 nanosecond (ns) at an input/output (I/O) pin or power rail, often originating from a charged object such as a human body or another conductive item. This voltage spike, significantly higher than the circuit’s operating range, is sensed by the ESD device. The protection mechanism in the diode or BJT string is designed with a breakdown threshold slightly above the normal operating voltage yet below levels that would be damaging to the circuitry. As the ESD voltage climbs and reaches this breakdown threshold, the diodes or BJTs in the string enter a breakdown mode, creating a conductive path for the transient current.

In a diode string, each diode, e.g., VPNP1 and VPNP2, turns on as the ESD voltage exceeds the threshold and turns on the SCR (PNPN), providing a low-resistance discharge path for the ESD current. Alternatively, in a bipolar string, each transistor becomes forward biased under the ESD voltage, behaving like a switch that enables a continuous current path from the ESD event to ground. The bipolar junction transistors are designed to “turn on” when the ESD voltage rises above the safe operating threshold, allowing them to conduct high currents briefly, which safely dissipates the excess charge. This controlled conduction prevents the high voltage from reaching sensitive areas in the circuit.

As the breakdown occurs, the ESD device provides a low-resistance path through the diode or BJT string, effectively shunting the excessive ESD current away from the sensitive parts of the circuit to a ground or designated power rail. In a diode string, each diode breakdown stage sequentially reduces the resistance, directing the current through the device without allowing high voltage to interfere with the protected circuit. In a bipolar string, each forward-biased transistor acts collectively to create a low-resistance path that can handle substantial current flow (e.g., 1-12 amps during peak currents) for the brief duration of the ESD event.

Once the ESD event has dissipated and the voltage level returns to its normal range, the diode or BJT string exits its breakdown or forward-biased state. The device then reverts to a high-impedance mode, disconnecting from the circuit and resuming its inactive state. With the high impedance restored, the ESD protection device does not influence normal circuit operation and is now ready to protect against any future ESD events without impacting the regular functionality of the protected circuitry.

For a foundry technology, a typical ESD protection device must accommodate the standard I/O types designed for various semiconductor applications. A crucial requirement for these ESD devices is the inclusion of a low-voltage trigger SCR, such as a diode-triggered SCR. The low-voltage trigger SCR is essential for providing effective protection against transient voltage spikes that can occur during normal operation or handling of electronic components. This type of SCR activates at lower voltages, ensuring that the ESD protection engages promptly to safeguard the semiconductor devices from potential damage. However, the fabrication of trigger diodes within bulk silicon presents significant challenges. When trigger diodes are created in bulk, they inadvertently lead to the Darlington effect. The Darlington effect occurs when two transistors are combined in such a way that their current gains multiply, resulting in a much higher overall gain. While this can be advantageous in certain applications, in the context of ESD protection, it leads to undesirable electrical characteristics. Specifically, the Darlington effect can cause increased leakage currents and slower response times, which are detrimental to the rapid protection required during ESD events.

Moreover, the integration of trigger diodes in bulk silicon contributes to poor scaling. As semiconductor technology advances, there is a continuous push towards smaller feature sizes and higher integration densities. Poor scaling refers to the difficulty in maintaining performance and reliability as device dimensions shrink. In the case of bulk-triggered diodes, the larger physical size and inherent electrical properties hinder the ability to scale down effectively, limiting the overall efficiency and performance of the ESD.

The disclosed semiconductor device is a nano-sheet diode-triggered silicon-controlled rectifier (SCR). This configuration leverages the unique characteristics of nano-sheet diodes to initiate the triggering mechanism for the SCR. The nano-sheet diode functions as a sensitive and efficient triggering component, ensuring rapid activation of the SCR under specific electrical conditions. By incorporating this diode architecture, the SCR demonstrates enhanced performance in applications requiring precise control, such as electrostatic discharge (ESD) protection or other high-speed switching scenarios. The integration of the nano-sheet diode with the SCR structure provides significant advantages in terms of scaling, response time, and operational reliability, making it suitable for advanced semiconductor technologies.

Accordingly, the teachings herein provide methods and systems of nanosheet diode-triggered SCR structure. The techniques described herein may be implemented in a number of ways. Example implementations are provided below with reference to the following figures.

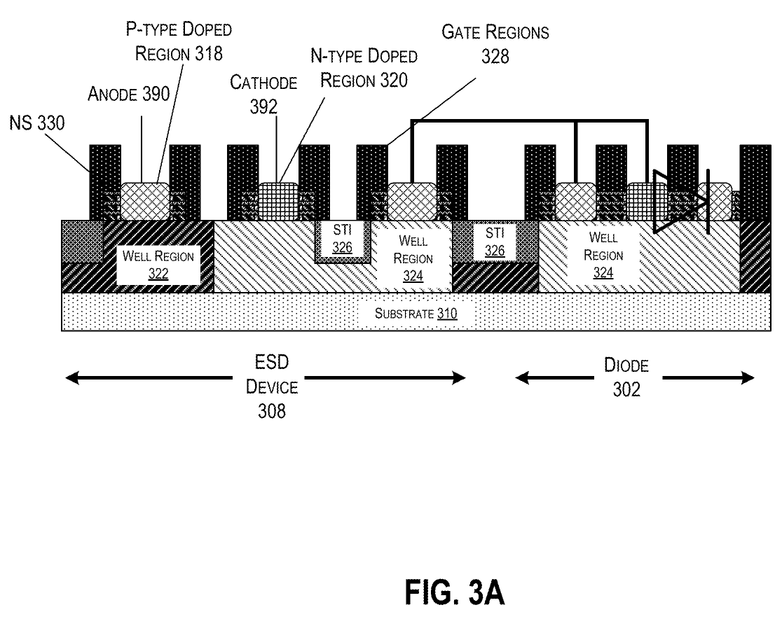

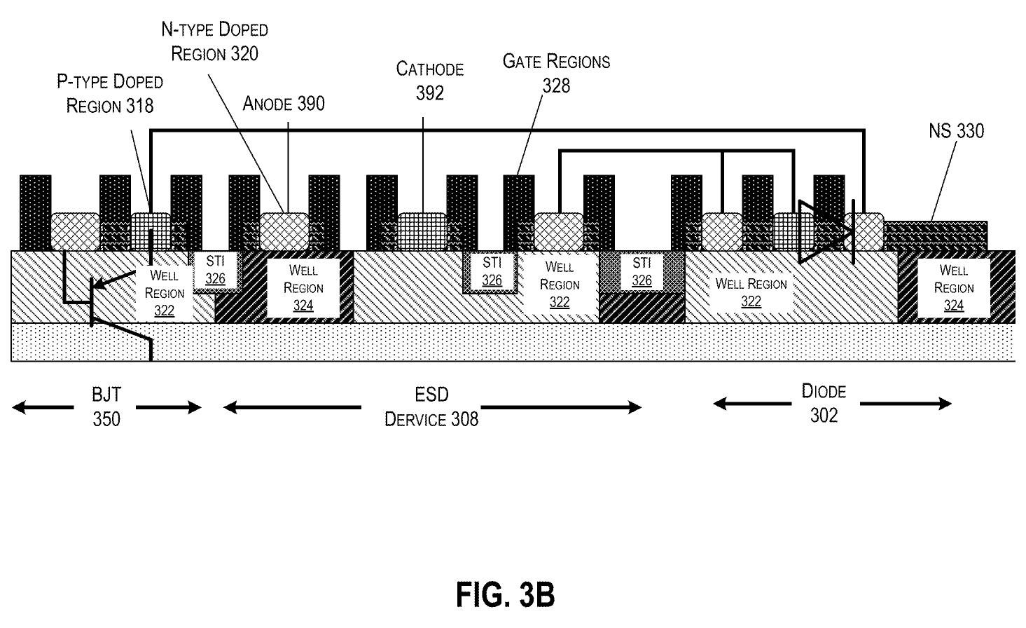

Reference now is made to FIGS. 3A-3B, which provides cross-section views of a semiconductor device, consistent with illustrative embodiments. FIG. 3A illustrates a semiconductor device with a true two-terminal diode coupled to a silicon-controlled rectifier in series, in accordance with an embodiment. In some embodiments, the semiconductor device includes a true two-terminal diode, diode 302. The diode 302 includes a first terminal and a second terminal, which serve as the primary points of electrical contact. The diode 302 facilitates unidirectional current flow, allowing electrical current to pass from the first terminal to the second terminal while preventing reverse current flow. This characteristic helps in protecting the device from undesired electrical surges and ensuring that current flows only in the intended direction, thereby maintaining the integrity of the device's electrical pathways.

In some embodiments, an ESD device 308 is electrically connected to the diode 302. The ESD device 308 can be a silicon-controlled rectifier, and/or a bipolar junction transistor. The ESD device 308 manages electrostatic discharge (ESD) events. When an ESD event occurs, the diode 302 modulates the trigger voltage applied to the ESD device 308, enabling it to activate and provide a protective response. The interaction between the diode 302 and ESD device 308 ensures that transient voltage spikes are effectively managed, safeguarding the device's internal components from potential damage caused by ESD events.

In some embodiments, the substrate 310 through which electrostatic discharge current directed can be a bulk silicon substrate. This bulk silicon substrate forms the foundational layer of the semiconductor device, providing mechanical support and facilitating the distribution of electrical currents across the device. The substrate 310's bulk silicon composition ensures conduction pathways, allowing high levels of electrostatic discharge current to pass through without compromising the device's structural integrity.

In some embodiments, the semiconductor device includes P-type doped regions 318 and N-type doped regions 320. These doped regions are strategically positioned to form the active areas of the diode 302. Additionally, the device features a first well region 322 and a second well region 324 adjacent to the first well region 322. The first well region 322 and the second well region 324 are located beneath the P-type doped regions 318 and N-type doped regions 320, respectively. This configuration allows for control over the electrical properties of the diode 302 and the ESD device 308, facilitating efficient current flow and robust ESD protection. The well regions provide the necessary dopant profiles and electrical isolation required for the proper functioning of the diode and trigger elements.

In some embodiments, the semiconductor device incorporates a set of shallow trench isolation, STI 326, positioned a level below the P-type doped regions 318 and N-type doped regions 320 and within the first well region 322 and the second well region 324. These shallow trench isolations electrically isolate the doped regions from one another, preventing unwanted current leakage and ensuring that electrical activity is confined to the designated active areas. The shallow trench isolation is fabricated using precise etching and deposition techniques that create narrow trenches filled with insulating material, such as silicon dioxide. This isolation technique enhances the device's overall performance by reducing (e.g., minimizing) electrical interference and maintaining the integrity of the current flow through the diode 302 and ESD device 308.

In some embodiments, the semiconductor device includes gate regions 328 positioned on two ends of each of the N-type doped regions 320 and the P-type doped regions 318. The gate regions 328 control the flow of charge carriers within the doped regions, thereby regulating the operation of the diode 302 and the ESD device 308. The gate regions 328 are fabricated using lithography and doping processes, ensuring that they are accurately aligned with the corresponding doped regions. By applying specific voltages to the gate regions 328, the device can modulate the electrical properties of the diode 302 and ESD device 308, allowing for dynamic control over their protective responses during ESD events.

In some embodiments, each of the N-type doped regions 320 and P-type doped regions 318 includes a plurality of nano-sheet channels, NS 330, situated between the corresponding doped region and the gate region. These nano-sheet channels are microscopic conductive pathways that facilitate the efficient movement of charge carriers, enhancing the electrical connectivity and performance of the semiconductor device. The nano-sheet channels provide high-density interconnections between the doped regions and the gate regions, ensuring that the device can respond swiftly and effectively to ESD events. This nano-sheet channel architecture is integral to achieving trigger voltage modulation, which can facilitate activating the ESD device 308 at the appropriate voltage levels.

In some embodiments, the plurality of nano-sheet channels, NS 330, includes alternative layers extended horizontally between the corresponding doped region and the gate region. The alternative layers are composed of silicon, which provides electrical conductivity and structural support for the nano-sheet channels. The horizontal extension of the silicon layers ensures that the nano-sheet channels maintain consistent electrical characteristics across the entire doped region and gate region interface. The layered silicon structure can facilitate achieving the necessary electrical performance and reliability, enabling the semiconductor device to effectively manage and distribute electrical signals during ESD events.

The semiconductor device’s design emphasizes the arrangement and fabrication of each component to achieve improved (e.g., optimal) electrical performance and mechanical stability. The true two-terminal diode, diode 302, ESD device 308, e.g., the SCR and/or BJT, and the substrate 310 are engineered to work together harmoniously, creating a cohesive and efficient electrical network. The inclusion of P-type doped regions 318, N-type doped regions 320, well regions, shallow trench isolation, STI 326, gate regions 328, and nano-sheet channels, NS 330, with alternative silicon layers ensures that the device operates efficiently and effectively, offering robust protection against ESD events while maintaining scalability and responsiveness through trigger voltage modulation. This integration allows the semiconductor device to provide reliable ESD protection, making it suitable for a wide range of electronic applications that require high-performance and stable operation.

In some embodiments, the semiconductor device includes a bulk silicon-controlled rectifier engineered to provide protection against electrostatic discharge by controlling the flow of electrical current within the device. The bulk SCR features nanosheet channels, which enhance the electrical conductivity and switching speed of the SCR, allowing it to respond swiftly to transient voltage spikes and effectively divert harmful currents away from sensitive components. In some embodiments, the true two-terminal diode is connected to the bulk SCR, which can modulate the trigger voltage required to activate the SCR. Such a modulation capability is helpful in maintaining the balance between sensitivity and robustness in ESD protection, allowing the device to respond accurately to varying levels of electrostatic discharge without unnecessary triggering.

The integration of the SCR with nanosheet channels and the two-terminal nanosheet trigger diode forms an efficient ESD protection network within the semiconductor device. The SCR provides a durable pathway for excess current, while the trigger diode ensures that the SCR activates only under specific conditions, preventing false triggers and enhancing the overall reliability of the protection mechanism. This combination leverages the strengths of both components, offering a scalable and effective solution for safeguarding electronic circuits against damaging electrostatic events. Additionally, the design of the semiconductor device emphasizes the seamless interaction between the SCR and the trigger diode. The nanosheet channels facilitate rapid charge carrier movement, reducing the response time of the SCR and ensuring that protection is enacted promptly. Meanwhile, the true two-terminal configuration of the trigger diode simplifies the overall architecture, reducing (e.g., minimizing) the number of required connections, and enhancing the device's compactness. This streamlined design improves manufacturing efficiency and contributes to the device's ability to operate effectively in high-density electronic applications where space and performance are critical.

FIG. 3B illustrates a semiconductor device with a true two-terminal diode and a BJT 350 coupled to a silicon-controlled rectifier in series, in accordance with an embodiment. In some embodiments, the semiconductor device includes a bulk SCR with a combination of a diode and bulk bipolars as trigger elements. The bulk SCR is a high-performance switching component designed to manage substantial electrical currents, providing robust protection against ESD events. Utilizing nanosheet channels, the bulk SCR achieves electrical performance by allowing for increased current density and faster switching capabilities. The nanosheet channels ensure that the SCR can respond rapidly to transient voltage spikes, effectively diverting harmful currents away from sensitive components and maintaining the integrity of the semiconductor device.

The diode serves as a true two-terminal diode within the semiconductor device, playing a role in modulating the trigger voltage applied to the bulk SCR. Thie diode is engineered using nanosheet technology, which provides control over its electrical characteristics. The two-terminal configuration of the diode allows for efficient scaling of the trigger voltage, ensuring that the bulk SCR activates at the optimal voltage levels necessary for effective ESD protection. By accurately modulating the trigger voltage, the diode enhances the reliability and responsiveness of the SCR, preventing unnecessary triggering and ensuring that protection is only engaged during genuine ESD events. Complementing the diode, the semiconductor device incorporates bulk Bipolars as additional trigger elements. These three-terminal bipolar junction transistors are integrated into the device to provide further control and stability to the triggering mechanism of the bulk SCR. The bulk bipolars offer enhanced switching performance and robustness, ensuring that the SCR can handle high-current conditions without degradation. By incorporating bulk bipolar transistors, the device benefits from improved thermal management and increased durability, allowing it to maintain consistent performance even under extreme electrical stress.

The combination of the bulk SCR, two-terminal diode, and three-terminal bulk bipolars creates an ESD protection network within the semiconductor device. This integrated approach leverages the strengths of nanosheet technology and bulk bipolar transistors to deliver an efficient and scalable protection solution. The Bulk SCR provides the primary switching capability, while the diode and bulk bipolars offer voltage modulation and control, respectively. Together, these components ensure that the semiconductor device can effectively manage and mitigate ESD events, safeguarding sensitive electronic circuits and maintaining the overall reliability and longevity of the device. Moreover, the use of nanosheet channels in the bulk SCR and the integration of nanosheet channels within the diode enable the semiconductor device to achieve superior electrical performance and scalability. The nanosheet structures facilitate high-density interconnections and rapid charge carrier movement, which are essential for modern high-speed and high-performance electronic applications. The bulk bipolars, with their switching capabilities, complement the nanosheet diodes by providing additional pathways for current flow, ensuring that the bulk SCR operates efficiently under various electrical conditions.

In some embodiments, the combination of these elements enhances the ESD protection capabilities of the semiconductor device and contributes to its overall efficiency and performance. The bulk SCR, supported by the diode and bulk bipolars, forms a cohesive and resilient protection mechanism that is suited for electronic systems requiring reliable and scalable ESD management.

The ESD pulse width can range from 0.7 nanoseconds (ns) to 100 ns, depending on the nature of the discharge event and the characteristics of the protection device. ESD protection device can be designed to handle these fast transient events by providing a low-resistance discharge path when an ESD strike occurs. An ESD event occurs at the input, i.e., anode 390, which can be a sensitive node in an integrated circuit. When the input voltage due to an ESD strike reaches the turn-on voltage of the triggering path, the trigger elements within the protection device begin conducting. The trigger elements can be implemented using two-terminal (2T) diodes, or a combination of 2T diodes and a three-terminal (3T) bulk vertical PNP (VPNP) transistor.

Once the trigger elements enter forward bias mode, the trigger elements generate a current that biases the p-well (PW) of the SCR. The SCR can be a four-layer device that consists of alternating p-type and n-type semiconductor regions, forming a pnpn structure. When the SCR is biased correctly, its internal pnp and npn transistors enter a regenerative feedback loop, meaning that each transistor drives the other into conduction. This results in a rapid reduction in resistance between the anode 390 and cathode 392, creating a low-impedance discharge path for the ESD current. This mechanism allows the device to quickly clamp the voltage and safely dissipate the excess charge.

In some embodiments, since the trigger elements are exclusively 2T diodes, the Darlington effect is not present, ensuring that the trigger voltage scales linearly with the number of 2T diodes. This provides a predictable and controlled triggering mechanism, which is important for reliable ESD protection. In some embodiments, the last trigger element in the series could be a bulk VPNP transistor. This transistor plays a role in improving the turn-on speed of the SCR by injecting holes into the p-well region. This hole injection mechanism facilitates a quicker biasing of the SCR, ensuring that it turns on faster and effectively shunts the ESD current before any damage can occur to the protected circuitry. In some embodiments, only the last trigger element in this configuration is a bulk VPNP, while the preceding elements remain 2T diodes.

It is essential to note that while the SCR is the primary ESD discharge element, it is not the trigger element itself. Instead, it relies on the trigger elements to initiate conduction. The trigger elements and the SCR structure are fabricated simultaneously during the semiconductor manufacturing process to ensure proper integration and optimal performance. Furthermore, shallow trench isolation (STI) regions are placed at the bottom of the n-type and p-type diffusions. Instead of being directly underneath these diffusion regions, the STI is positioned adjacent to them, which helps optimize the performance of the ESD protection device by minimizing parasitic effects while maintaining effective current conduction paths.

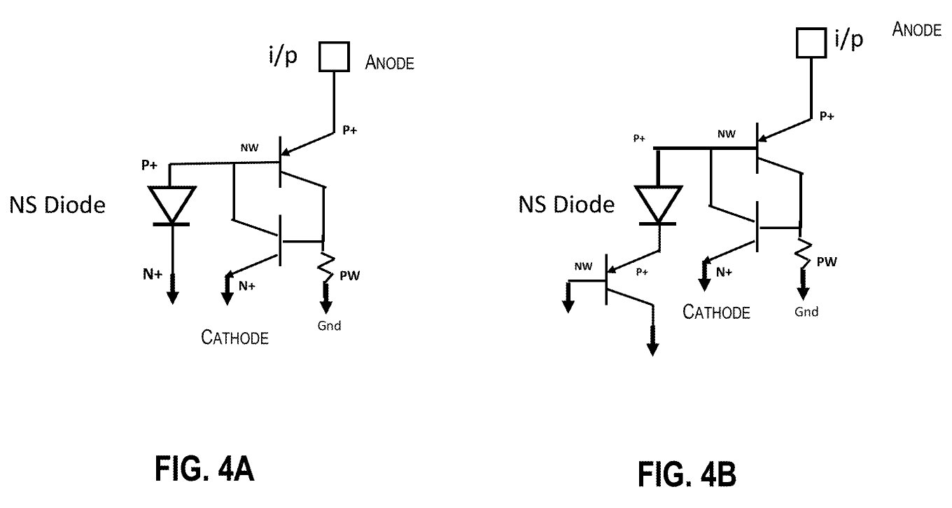

In some embodiments, it will be understood that other types of substrates, other than silicon, may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys. In various embodiments, the substrate can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top. FIG. 4A-4B illustrates exemplary circuitry of the semiconductor device shown in FIGS. 3A-3B, respectively.

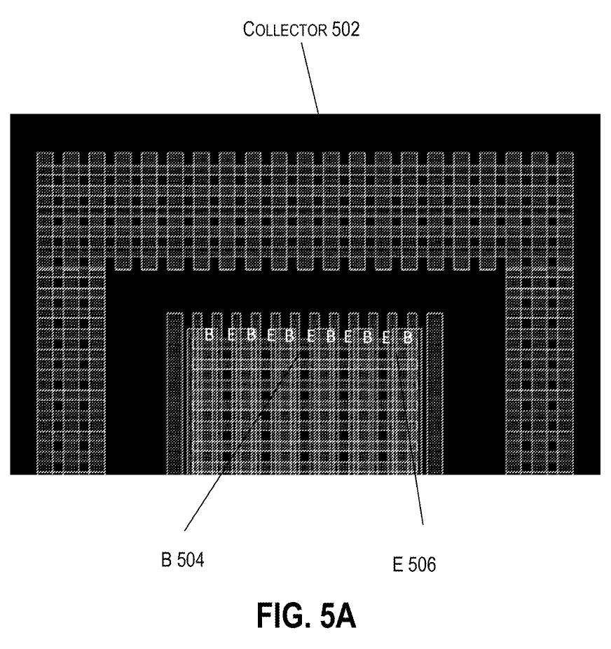

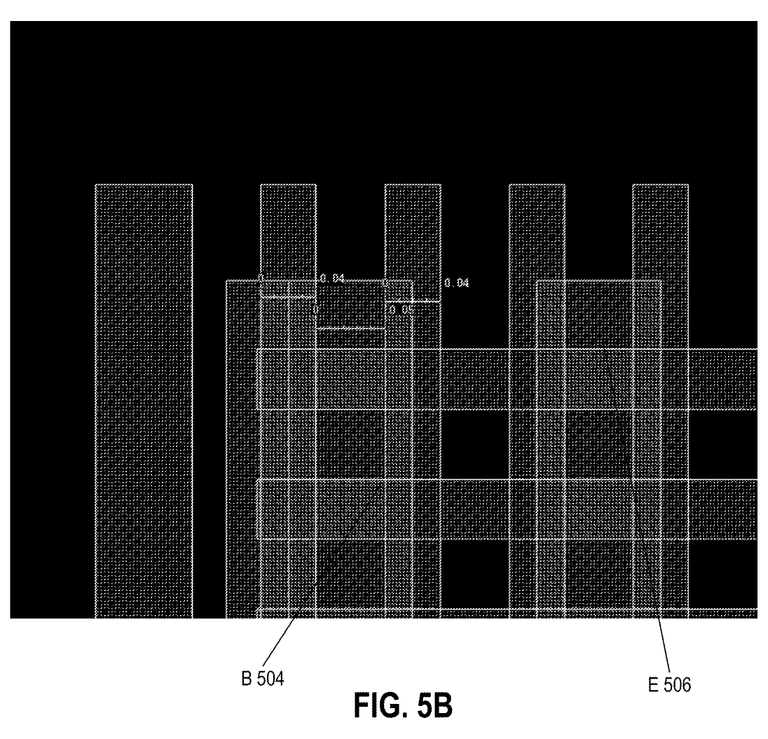

FIGS. 5A-5B illustrate top views of the semiconductor device, in accordance with some embodiments. FIGS. 5A-5B illustrate the collector 502, e.g., ground, the base, B 504, and the emitter, E 506. In some embodiments, the base is doped with an N-type dopant/P-type dopant and the emitter is doped with a P-type dopant/N-type dopant.

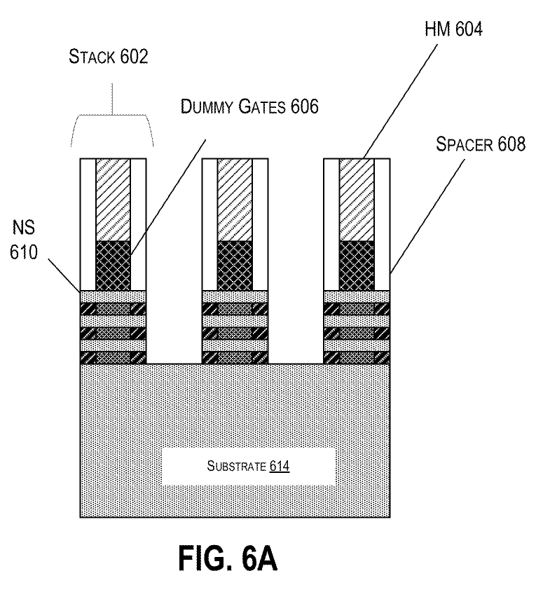

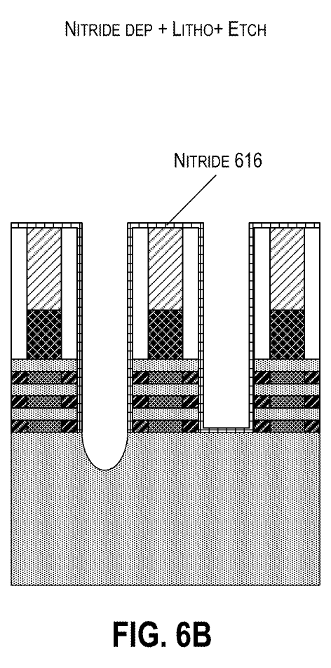

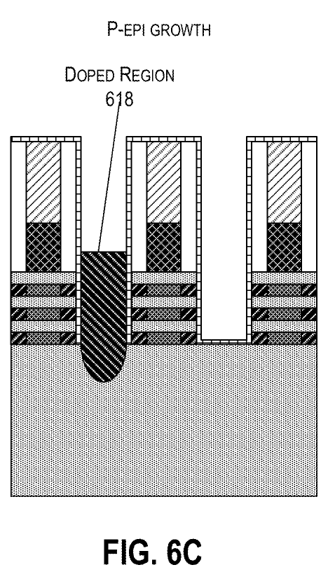

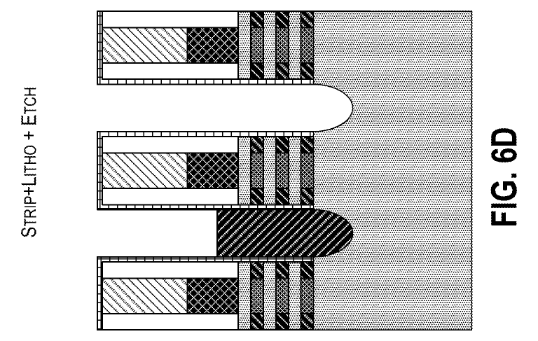

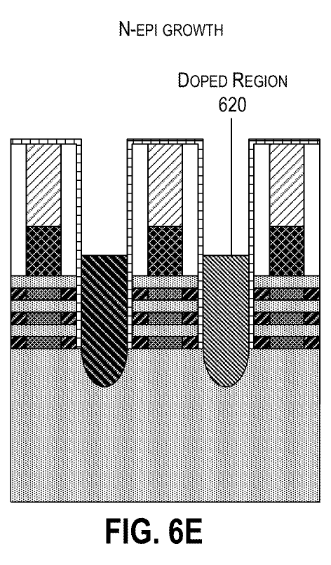

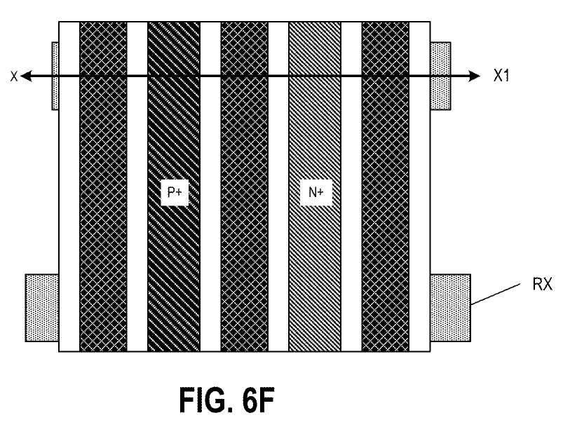

FIGS. 6A-6E illustrate the process acts to fabricate the semiconductor device, in accordance with some embodiments. As shown in FIG. 6A, the semiconductor device can include a stack 602 of hard mask, HM 604, and dummy gates 606, which a layer of a spacer 608 covers the sidewalls of the stacks 602. Nanosheet channels, NS 610, are extended horizontally along the channel. The stacks are formed over a substrate 614. As shown in FIG. 6B, a layer of nitride 616 is deposited, e.g., by lithography, over the stacks 602 and the surface of the substrate 614. Portions of the surface of the substrate 614 can be removed, e.g., by etching. As shown in FIG. 6C, a first doped region 618 is formed over the removed portions of the substrate. As shown in FIG. 6D, portions of the substrate are removed, which can be used to form the second doped region 620, as shown in FIG. 6E. FIG. 6F illustrates a top view of the semiconductor device during the process acts as shown in FIGS. 6A-6E.

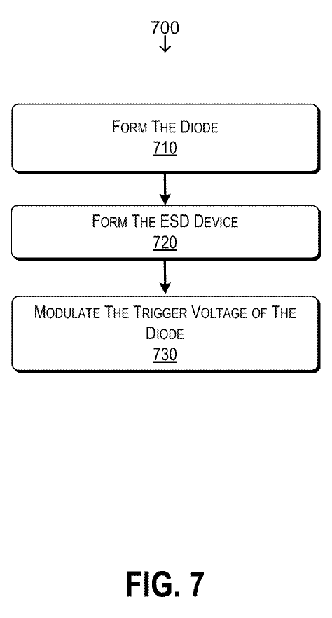

FIG. 7 illustrates a block diagram of a method 700 for forming the semiconductor device, in accordance with some embodiments. As shown by block 710 , a diode is formed.

As shown by block 720 , an ESD is electrically connected to the diode.

As shown by block 730 , a trigger voltage applied to the diode is modulated via the diode.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a diode, wherein the diode is a true two-terminal diode with a first terminal and a second terminal; and
an electrostatic discharge device, ESD, electrically connected to the diode, the ESD comprising an anode and a cathode;
wherein the diode is a triggering element and is operative to modulate a trigger voltage of the ESD, and wherein an ESD event occurs via the anode .

2. The semiconductor device of claim 1, wherein the ESD is at least one of: a silicon-controlled rectifier, or a bipolar junction transistor.

3. The semiconductor device of claim 1, further comprising a substrate, wherein the substrate is a bulk silicon substrate.

4. The semiconductor device of claim 1, further comprising:
one or more P-type doped regions;
one or more N-type doped regions;
a first well region; and
a second well region adjacent to the first well region, wherein the first well region and the second well region are located below the one or more P-type doped regions and the one or more N-type doped regions.

5. The semiconductor device of claim 4, further comprising:
a set of shallow trench isolation (STI) located a level below the one or more P-type doped regions and the one or more N-type doped regions and within the first well region and the second well region; and
a set of gate regions on two ends of each of the one or more N-type doped regions and the one or more P-type doped regions.

6. The semiconductor device of claim 4, wherein each of the one or more N-type doped regions and the one or more P-type doped regions further comprises a plurality of nano-sheet channels between a corresponding doped region and a gate region.

7. The semiconductor device of claim 6, wherein the plurality of nano-sheet channels comprises alternative layers extended horizontally between the corresponding doped region and the gate region.

8. The semiconductor device of claim 7, wherein the alternative layers include silicon.

9. A method of fabricating a semiconductor device, the method comprising:
forming a diode, wherein the diode is a true two-terminal diode with a first terminal and a second terminal;
forming an electrostatic discharge device, ESD comprising an anode and a cathode; and
electrically connecting the ESD to the diode,
wherein the diode is a triggering element and is operative to modulate a trigger voltage of the ESD, and wherein an ESD event occurs via the anode.

10. The method of claim 9, wherein the ESD is at least one of: a silicon-controlled rectifier, or a bipolar junction transistor.

11. The method of claim 9, further comprising forming a substrate, wherein the substrate is a bulk silicon substrate.

12. The method of claim 9, further comprising:
forming one or more P-type doped regions;
forming one or more N-type doped regions;
forming a first well region; and
forming a second well region adjacent to the first well region, wherein the first well region and the second well region are located below the one or more P-type doped regions and the one or more N-type doped regions.

13. The method of claim 12, further comprising:
forming a set of shallow trench isolation (STI) located a level below and adjacent to the one or more P-type doped regions and the one or more N-type doped regions and within the first well region and the second well region; and
forming a set of gate regions on two ends of each of the one or more N-type doped regions and the one or more P-type doped regions.

14. The method of claim 12, wherein forming the one or more N-type doped regions and the one or more P-type doped regions further comprises forming a plurality of nano-sheet channels between a corresponding doped region and a gate region.

15. The method of claim 14, wherein forming the plurality of nano-sheet channels comprises forming alternative layers extended horizontally between the corresponding doped region and the gate region.

16. The method of claim 15, wherein the alternative layers include silicon.

17. A semiconductor device, comprising:
a diode; and
an electrostatic discharge device, ESD, electrically connected to the diode, and
wherein:
the ESD is at least one of: a silicon-controlled rectifier, or a bipolar junction transistor.

18. The semiconductor device of claim 17, further comprising:
one or more P-type doped regions;
one or more N-type doped regions;
a first well region; and
a second well region adjacent to the first well region, wherein the first well region and the second well region are located below the one or more P-type doped regions and the one or more N-type doped regions.

19. The semiconductor device of claim 18, further comprising:
a set of shallow trench isolation (STI) located a level below the one or more P-type doped regions and the one or more N-type doped regions and within the first well region and the second well region; and
a set of gate regions on two ends of each of the one or more N-type doped regions and the one or more P-type doped regions.

20. The semiconductor device of claim 18, wherein:
each of the one or more N-type doped regions and the one or more P-type doped regions further comprises a plurality of nano-sheet channels between a corresponding doped region and a gate region,
the plurality of nano-sheet channels comprises alternative layers extended horizontally between the corresponding doped region and the gate region, and
the alternative layers include silicon.
